(19) United States
(12) Patent Application Publication
(10) Pub. No.: US 2016/0013349 A1
(43) Pub. Date: Jan. 14, 2016

(54) Photoelectric Conversion Device and Method for Manufacturing Photoelectric Conversion Device

(71) Applicant: Yoriyasu OZAKI, Kizugawa-shi, Kyoto (JP)

(72) Inventor: Yoriyasu Ozaki, Kizugawa-shi (JP)

(21) Appl. No.: 14/772,266

(22) PCT Filed: Feb. 28, 2014
(86) PCT No.: PCT/JP2014/055147

§ 371 Date: Sep. 2, 2015

(30) Foreign Application Priority Data
Mar. 4, 2013 (JP) 2013-042244

(51) Int. Cl. H01L 31/07; H01L 31/0352; H01L 31/18

(52) U.S. Cl. CPC H01L 31/07; H01L 31/1864; H01L 31/03529

(57) ABSTRACT

A photoelectric conversion device includes a photoelectric conversion part, a first electrode, and a second electrode. The photoelectric conversion part includes a first layer and a second layer. The first and second layers are joined to each other to form a Schottky junction. The first electrode is formed on the first layer. The second electrode is formed on the second layer without electrical contact with the first layer in order to extract photocarriers, which move along an interface of the Schottky junction, in conjunction with the first electrode.

### CROSS-REFERENCE TO RELATED APPLICATIONS

The present application is a U.S. National Stage filing under 35 U.S.C. §371 from International Application No. PCT/JP2014/055147 filed on Feb. 28, 2014, which in turn claims priority to Japanese Patent Application No. 2013-042244 filed on Mar. 4, 2013.

### BACKGROUND OF THE INVENTION

1. Technical Field

The invention relates to Schottky-type photoelectric conversion device, and a manufacturing method of the photoelectric conversion device.

1. Background Art

The accidents at nuclear power plants following the Great East Japan Earthquake prompted a demand for alternative energy sources to nuclear energy, and expectations are high that photovoltaic power generation will play a part to meet such a demand. For further utilization of photovoltaic power generation, it is required to enhance performance of existing solar cells and also develop next-generation solar cells. Solar cells drawing attention as next-generation solar cells include dye-sensitized solar cells and organic thin-film solar cells. A fresh new proposal is a CoSi thin-film photoelectric conversion element developed by the inventor (see Non-Patent Literature 1 and Patent Literature 1).

As illustrated in FIG. 13, a CoSi thin-film photoelectric conversion element 1 at the outset of the development includes a photoelectric conversion part 2 consisting of an Si substrate 4 and a CoSiₓ layer 3 laminated on the Si substrate 4, and a positive electrode 5 and a negative electrode 6 that are formed on the surface of the CoSiₓ layer 3.

### CITATION LIST EQUIVALENT

### Non-Patent Literature

Non-Patent Literature 1: Takanari Yasui. Development of the Visible to-IR Solar Cells Utilized Co-Silicides toward Cool Earth. Annual Report of the Murata Science Foundation 2009; No. 23.

### Patent Literature

Patent Literature 1: Japanese Patent No. 5067710

### SUMMARY OF INVENTION

### Technical Problem

However, the above-described conventional element has a low open output voltage of the element (cell), i.e. about 0.1 V or lower, which is a problem (hereinafter referred to as the first problem) that the conventional element is still unsuitable for practical use as a solar cell. Even if known carrier leak measures are taken such as an addition of a side diode between the CoSiₓ layer 3 and the negative electrode 6, the side diode becomes bipolar during operation, and accordingly photocarriers cannot be sufficiently separated. Thus, it is difficult to readily increase an open output voltage. As illustrated in FIG. 13, only a limited part of incident light L can contribute to power generation, i.e. light incident on a region ER within 1 mm from the positive electrode 5, which entails another problem (hereinafter referred to as the second problem) that it is difficult to increase efficiency of photoelectric conversion.

The invention is devised against the above backdrop and aimed mainly at providing a photoelectric conversion device with high open output voltage and capable of increasing efficiency of photoelectric conversion, and also providing a manufacturing method of the photoelectric conversion device.

### Solution to Problem

As illustrated in FIG. 1, a photoelectric conversion device 100 of the invention includes a first layer 11 and a second layer 12 that are joined to each other to form a Schottky junction; a first electrode 20 formed on the first layer 11; and a second electrode 30 formed on the second layer 12 and out of electrical contact with the first layer 11 in order to extract photocarriers, which move along an interface S of the Schottky junction, in conjunction with the first electrode 20.

In the above photoelectric conversion device, the first electrode 20 and the second electrode 30 are electrostatically separated via a Schottky barrier, enhancing the separation of photocarriers generated near the interface S of the Schottky junction. This ensures an output potential appearing between the first electrode 20 and the second electrode 30 (at a level equal to or higher than existing solar cells). The photoelectric conversion device can thus solve the first problem and can also contribute to practical use as a solar cell. In addition, the separation of photocarriers is enhanced as described above, and the photocarriers move in a uniform direction. This prevents reduction of photoinduced current, unlike the conventional case, without limiting the region of the incident light to the vicinity of the positive electrode. The photoelectric conversion device can thus solve the first problem and can also solve the second problem and can also enhance efficiency in photoelectric conversion. In addition, in view of the fact that photocarriers move along the interface of the Schottky junction, it is possible to further reduce the thickness of the device by eliminating partial thickness that is not involved in the movement.

It should be appreciated that the photoelectric conversion part herein may have any configuration so long as it is a Schottky type in which photocarriers move along an interface of a Schottky junction. Similarly, the first electrode and the second electrode may be at any positions relative to the first layer and the second layer so long as they have a function of capable of extracting photocarriers moving along the interface of the Schottky junction.

The photoelectric conversion device may preferably have, in addition to the above basic configuration, an insulating member interposed between an end of the first layer and the second electrode.

The photoelectric conversion device having this configuration produces, in addition to the above basic effects, an effect of facilitating a fine adjustment of an open output voltage by changing a material, etc. of the insulating member.

The photoelectric conversion part may preferably configured such that the first layer be made of CoSiₓ, while the second layer be made of Si.

The photoelectric conversion device having this configuration can perform photoelectric conversion of light of a wide wavelength band, from a visible region to an infrared region, and can generate power with not only light incident on the front surface of the device but also light incident on the back surface. Accordingly, the photoelectric conversion device can produce, in addition to the above basic effects, an effect of further increasing efficiency of photoelectric conversion. Furthermore, the photoelectric conversion device can generate power also in the nighttime and even with the use of radiant heat waste in urban areas, and the device can by extension greatly contribute to the prevention of global warming.

A manufacturing method of the photoelectric conversion device of the invention includes forming a pattern of the second electrode on a Si substrate corresponding to the second layer; thereafter forming on the Si substrate a pattern of Co, which is a material of the first layer, and annealing the pattern to form the first layer and annealing the pattern to form the first layer; and thereafter forming a pattern of the first electrode on the first layer.

In the manufacturing method of the photoelectric conversion device configured as described above, the photoelectric conversion device can be manufactured by a simple semiconductor process such as metal thin-film formation or annealing, making it possible to reduce the cost of the device in itself.

It should be noted that the first layer of the photoelectric conversion part is not limited to CoSiₓ but may be FeSiₓ, WSiₓ, NiSiₓ, AlSiₓ, or TiSiₓ, for example. A photoelectric conversion device using such metal silicides can be manufactured in a similar method as described above, in which case similar effects can be achieved.

The photoelectric conversion part may have a configuration, in addition to the above, that the first layer is made of a metal or alloy and the second layer is made of another metal or alloy differing in work function from the metal or alloy of the first layer. An intermediate insulating layer may be interposed between the first layer and the second layer.

The photoelectric conversion device having this configuration mainly uses a metal or an alloy, so that the base substrate is less likely to be exposed to high temperature during the manufacturing process. This produces an effect, in addition to the above basic effects, that it is possible to use a base substrate of a material that cannot be used at high temperatures. In this regard, it is easy to provide flexibility to the photoelectric conversion device.

In this case, another manufacturing method of the photoelectric conversion device of the invention includes forming the second layer on a surface of a base substrate; thereafter forming a pattern of the intermediate insulating layer and a pattern of the first layer sequentially on the second layer; thereafter forming a pattern of the second electrode on the second layer; and there before or thereafter forming a pattern of the first electrode on the first layer.

In the manufacturing method of the photoelectric conversion device configured as described above, the photoelectric conversion device can be manufactured by a simple semiconductor process such as metal thin-film formation or electrode formation. The method therefore produces an effect, in addition to the above basic effects, of readily reducing the cost of the device.

It is more preferable that the photoelectric conversion part have a metal nanostructure including projections of an order of submicron or nanometer formed in a periodic or random manner on a surface of the first layer so that light of a predetermined wavelength band contained in incident light is effectively absorbed by surface plasmon resonance.

The surface plasmon resonance is a phenomenon in which photocarriers on a surface of a metal resonates with an electric field of light and vibrate when the metal is irradiated with light. This phenomenon is remarkably observed on a surface of a metal having metal nanoparticles or a microprojection structure. When light of a predetermined wavelength band, which includes not only a partial wavelength band but also all wavelength bands in some cases, is absorbed in a metal due to surface plasmon resonance (plasmon absorption), the photocarriers of the metal are placed into a high energy condition.

The photoelectric conversion device having this configuration, utilizing surface plasmon resonance, produces an effect, in addition to the above basic effects, that it is possible to further increase efficiency of photoelectric conversion. The photoelectric conversion device can also absorb light of an infrared wavelength band (or light of all wavelength bands), for example, to perform photoelectric conversion by adjusting spaces between the adjacent projections, heights of projections, or lengths of projections in the metal nanostructure. Accordingly, the photoelectric conversion device can generate power also in the nighttime and even with the use of radiant heat waste in urban areas, and the device can by extension greatly contribute to the prevention of global warming.

It should be noted that the metal nanostructure may be of any material so long as its projects have outer surfaces of a metal. The projections may be of any shape, may vary in any manner in height, and may have any layout.

The photoelectric conversion device of the invention in such a case is manufactured by another method including forming a pattern of the projections on the surface of the first layer of the photoelectric conversion part; and thereafter annealing the pattern so as to form the metal nanostructure in the photoelectric conversion part.

In the manufacturing method of the photoelectric conversion device configured as described above, the metal nanostructure can be manufactured by a simple semiconductor process such as printing or annealing. The method therefore makes it possible to further improved efficiency of photoelectric conversion of the device in itself and further reduce the cost of the device. Annealing after the formation of the projections enhances adhesiveness of the projections to the outer surface of the photoelectric conversion part. Further, microparticles of the metal material can diffuse along the surface of the photoelectric conversion part to form multiple branches as an aggregate of a francl structure. This increases mobility of photocarriers and improves electric characteristics.

Another photoelectric conversion device of the invention includes a photoelectric conversion part including a junction body, and a first electrode and a second electrode in order to extract photocarriers generated on the junction body. The photoelectric conversion part has a metal nanostructure including projections of an order of submicron or nanometer formed in a periodic or random manner on a surface of a layer of incidence of the junction body so that light of a predetermined wavelength band contained in incident light is effectively absorbed by surface plasmon resonance.

The photoelectric conversion part described here may have any configuration having a function of photoelectric conversion at the junction body through absorption of light. Similarly, the first electrode and the second electrode may be at any positions relative to the outer surface of the photoelectric conversion part, so long as they have a capability of extracting photocarriers generated in the junction body. the metal nanostructure may be of any material so long as its projects have outer surfaces of a metal. The projections may be of any shape, may vary in any manner in height, and may have any layout.

The manufacturing method of the photoelectric conversion device configured as described above can increase efficiency of photoelectric conversion by utilizing the surface plasmon resonance described above. The photoelectric conversion device can also perform photoelectric conversion of light of an infrared wavelength band (or all wavelength bands), for example, by adjusting spaces between the adjacent projections, etc. Accordingly, the photoelectric conversion device can generate power also in the nighttime and even with the use of radiant heat waste in urban areas, and the device can by extension greatly contribute to the prevention of global warming.

In this case, another manufacturing method of the photoelectric conversion device of the invention includes forming a pattern of the projections on the surface of the layer of incidence the photoelectric conversion part; and thereafter annealing the pattern so as to form the metal nanostructure on the photoelectric conversion part.

In the manufacturing method of the photoelectric conversion device configured as described above, the metal nanostructure can be manufactured by a simple semiconductor process such as printing or annealing. The method therefore makes it possible to further improved efficiency of photoelectric conversion of the device in itself and further reduce the cost of the device. Annealing after the formation of the projections enhances adhesiveness of the projections to the outer surface of the photoelectric conversion part. Further, microparticles of the metal material are diffused along the surface of the photoelectric conversion part to form multiple branches as an aggregate of a francl structure. This increases mobility of photocarriers and improves electric characteristics. The method also enhances adhesiveness of the projections, increases mobility of photocarriers, and accordingly improves electric characteristics.

### BRIEF DESCRIPTION OF THE DRAWINGS

The present invention can be even more fully understood with the reference to the accompanying drawings which are intended to illustrate, not limit, the present invention.

FIG. 1 is a schematic sectional view of a photoelectric conversion device schematically illustrating the invention.

FIG. 2 is an explanatory view for the first embodiment of the invention, i.e. a schematic vertical sectional view of a photoelectric conversion device according to the first embodiment.

FIG. 3 is a schematic view illustrating steps of a manufacturing method of the photoelectric conversion device.

FIG. 4 is a graph illustrating a wavelength sensitivity characteristic of Co, which is the basic material of a photoelectric conversion part of the photoelectric conversion device.

FIG. 5 is a schematic view illustrating an example of how the photoelectric conversion device is used.

FIG. 6 is an explanatory view for the second embodiment of the invention, i.e. a schematic vertical sectional view of a photoelectric conversion device according to the second embodiment.

FIG. 7 is a schematic view illustrating steps of a manufacturing method of the photoelectric conversion device.

FIG. 8 is a graph showing power generation energy characteristic versus wavelength of the photoelectric conversion device.

FIG. 9 is a schematic view illustrating an example how the photoelectric conversion device is used.

FIG. 10 is an explanatory view for the third embodiment of the invention, i.e. a schematic view of a photoelectric conversion device according to the third embodiment.

FIG. 11 is a schematic view illustrating steps of a manufacturing method of the photoelectric conversion device.

FIG. 12 is a graph illustrating a relation between a spatial frequency of a metal nanostructure and an spectral intensity of light absorption in the photoelectric conversion device.

FIG. 13 is a schematic sectional view of a conventional CoSi thin-film photoelectric conversion element.

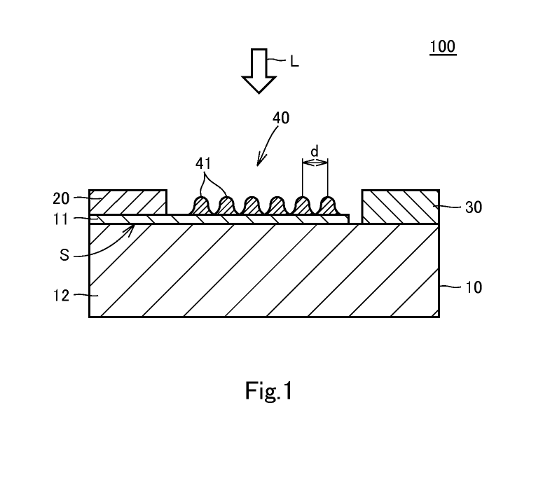

### DESCRIPTION OF EMBODIMENTS

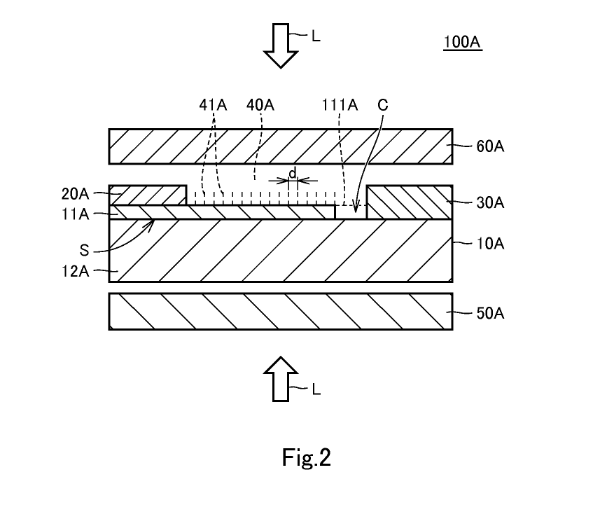

Embodiments of the invention will be described below with reference to FIGS. 2 to 12.

### First Embodiment

A photoelectric conversion device 100A illustrated in FIG. 2 includes a photoelectric conversion part 10A having a CoSiₓ layer 11A (corresponding to a first layer) and a Si layer 12A (corresponding to a second layer), the CoSiₓ layer 11A and the Si layer 12A being joined to each other to form a Schottky junction; an anode electrode 20A (corresponding to a first electrode) formed on a surface of the CoSiₓ layer 11A; and a cathode electrode 30A (corresponding to a second electrode) formed on the Si layer 12A and out of electrical contact with the CoSiₓ layer 11A in order to extract photocarriers, which move along an interface of the Schottky junction (Schottky interface S), in conjunction with the anode electrode 20A.

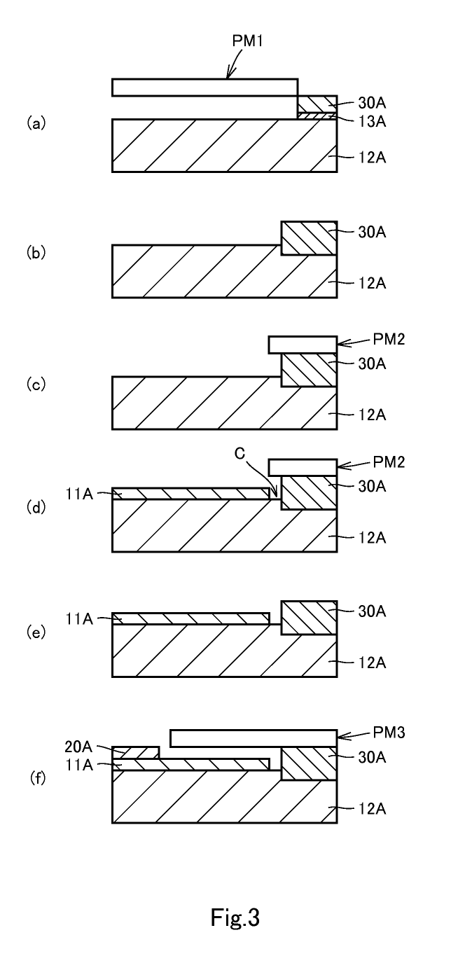

With the above configuration, the device 100A is adapted to perform photoelectric conversion of light (incident light L) incident upon the front surface and the back surface of the device and output power obtained by the conversion to the outside via the anode electrode 20A and the cathode electrode 30A. It should be noted that the CoSiₓ layer 11A is formed by self-organizing the interface between Co and Si (see FIG. 3) so as to excite photocarriers by utilizing nanosilicide of the CoSiₓ layer 11A and nanostructure of the Si layer 12A. Therefore, the device 100A can perform photoelectric conversion of light of broad bandwidth, i.e. from visible to infrared.

The reference numeral 50A denotes a base plate, and the reference numeral 60A denotes a protection plate. Transparent glass or resin is used for both plates.

As for the photoelectric conversion part 10A, the Si layer 12A is n-type and has a (100) plane and a specific electrical resistance of 10 to 20 Ωcm, and the CoSiₓ layer 11A has a thickness of 8 to 9 nm in the present embodiment. There is a clearance C of about 500 to 1000 nm between the end of the CoSiₓ layer 11A and the cathode electrode 30A.

The CoSiₓ layer 11A is preferably made of CoSi2. The device 100A can be formed to have a total thickness of about 20 to 30 nm by eliminating partial thickness of the Si layer 12A of the photoelectric conversion part 10A, which is mainly the part that is not involved in photocarrier conduction, in view of the fact that photocarriers move along the Schottky interface S.

The anode electrode 20A in the present embodiment has a thickness of 500 nm and is made of Au. The cathode electrode 30A in the present embodiment has a thickness of 100 nm and is made of Au. These electrodes are joined respectively with the CoSiₓ layer 11A and the Si layer 12A such as to form ohmic junctions.

The electrode 20A is uniquely defined as an anode and the electrode 30A is uniquely defined as a cathode. This is because, unlike a conventional case, the cathode electrode 30A is out of electrical contact with the CoSiₓ layer 11A, making it possible to determine the moving direction of photocarriers (electrons/holes) generated near the Schottky interface S for each type of carriers. In the conventional case, each electrode can serve as an anode or a cathode due to contaminants mixed in a process of manufacturing a device or due to other disturbances, and this causes difficulty in increasing an open output voltage of a conventional element. However, the inventor newly tracked down the cause of this problem and has radically solved the problem with a very simple method of changing a relative positional relationship of the CoSiₓ layer 11A.

Using a p-type as the Si layer 12A can reverse the anode-cathode relation of the electrodes. In addition, if an insulating member 111A of SiO2, SiN2, insulating organic substance, or other material is interposed in the clearance C as indicated by a broken line in FIG. 2, it is possible to finely adjust the open output voltage by selecting an appropriate material for the insulating member 111A. Further, if desired optical characteristics are not obtained, it is preferable to configure the photoelectric conversion part 10A to have a metal nanostructure 40A. The metal nanostructure 40A is such that projections 41A are formed in a periodic or random manner at intervals d, etc. of an order of submicron (10-7 m) or nanometer (10-9 m) in a region between the anode electrode 20A and the cathode electrode 30A on the surface of the CoSiₓ layer 11A, so that light of a predetermined wavelength band contained in incident light L is effectively absorbed by surface plasmon resonance. The metal nanostructure 40A will be described in detail below.

The following describes a method of manufacturing the photoelectric conversion device 100A configured as described above, with reference to FIG. 3.

First, a silicon substrate already subjected to RCA cleaning is prepared as the Si layer 12A. The Si layer 12A is subjected to patterning using a photomask PM1 by sputtering or other process to sequentially form a Ti layer 13A with a thickness of about 10 nm and an Au layer with a thickness of about 200 nm on the surface of the Si layer 12A (see FIG. 3(a)). Annealing is then performed at about 500 degrees for about 10 minutes in a nitrogen atmosphere to form the cathode electrode 30A on the surface of the Si layer 12A (see FIG. 3(b)) in an ohmic manner.

Next, patterning is conducted using a photomask PM2 by sputtering or other process to form a Co layer with a thickness of about 8 to 9 nm (see FIG. 3(d)). The clearance C is created in this process. Then, lamp annealing is performed at about 500 degrees for about 5 minutes in a nitrogen atmosphere. The subsequent 10-minute cooling results in a pattern formation of the CoSix layer 11A on the surface of the Si layer 12A (see FIG. 3(e)).

Next, patterning is conducted using a photomask PM3 by sputtering or other process to form an Au layer with a thickness of about 200 nm, i.e. the anode electrode 20A on the surface of the CoSix layer 11A (see FIG. 3(f)).

The projections 41A of the metal nanostructure 40A may be formed concurrently with the formation of the anode electrode 20A on the surface of the CoSix layer 11A as detailed below.

Through a series of the above processes the photoelectric conversion part 10A is fabricated. The photoelectric conversion part 10A is combined with the base plate 50A and the protection plate 60A along with internal wiring to fabricate the photoelectric conversion device 100A as illustrated on the left side in FIG. 5. The Si layer 12A may not be a silicon substrate as in the above embodiment, but a crystal of silicon may be grown on the surface of the base plate 50 to use the crystal as the Si layer 12A.

When the photoelectric conversion device is used as a tandem type, multiple photoelectric conversion devices 100A are stacked as shown on the right side in FIG. 5 and electrically connected to each other in parallel, in series, or in series parallel. The reference numerals 101A and 102A denote external output terminals.

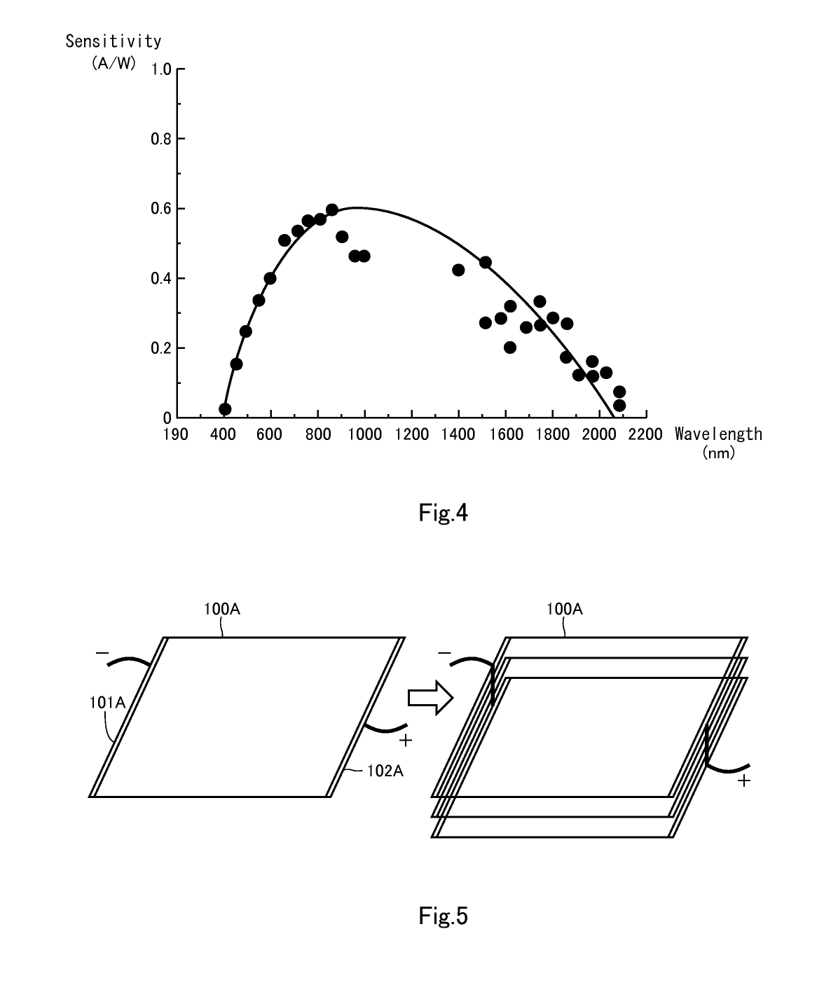

The photoelectric conversion device 100A thus fabricated provides a photoelectric conversion efficiency of about 10 to 12%, and an open output voltage of about 0.8 to 1.2V. The production cost is about one tenth of that of a conventional device at the same output level. The photoelectric conversion device 100A especially enables photoelectric conversion in a wide band from visible to infrared regions and exhibits similar characteristics to Co used as a basic material of the photoelectric conversion part 10A (see FIG. 4).

### Second Embodiment

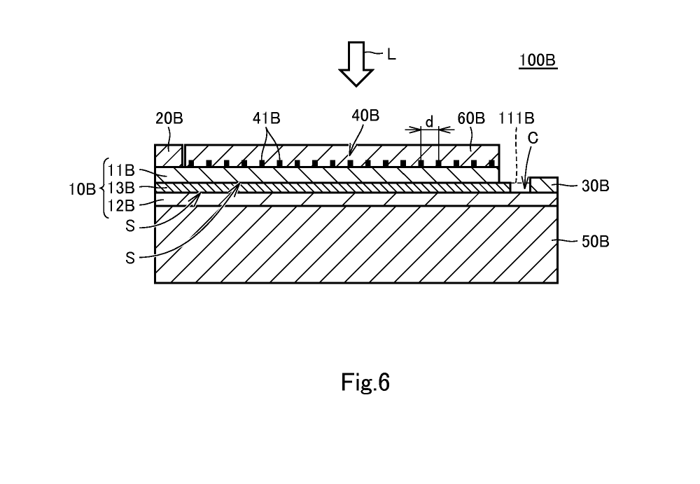

A photoelectric conversion device 100B illustrated in FIG. 6 includes a photoelectric conversion part 10B having a Pt layer 11B (corresponding to a first layer) and a Cr/Au layer 12B (corresponding to a second layer), the Pt layer 11B and the Cr/Au layer 12B being joined to each other to form a Schottky junction via a Cr2O3 layer 13B (corresponding to an intermediate insulating layer); an anode electrode 20B (corresponding to a first electrode) formed on the surface of the Pt layer 11B; a cathode electrode 30B (corresponding to a second electrode) formed on the Cr and Au layer 12B and out of electrical contact with the Pt layer 11B in order to extract photocarriers, which move along interfaces of the Schottky junctions (Schottky interfaces S) between Pt, Cr2O3, and Cr, in conjunction with the anode electrode 20B; and a metal nanostructure 40B formed on the surface of the Pt layer 11B.

With the above configuration, the device 100B is adapted to perform photoelectric conversion of light (incident light L) incident upon the front surface and the back surface of the device and output power obtained by the conversion to the outside via the anode electrode 20B and the cathode electrode 30B. It should be noted that the photoelectric conversion part 10B is provided with the metal nanostructure 40B, so that light of all wavelength bands contained in the incident light L is effectively absorbed by surface plasmon resonance.

The reference numeral 50B denotes a base plate, and the reference numeral 60B denotes a protection plate. Transparent glass or resin is used for both plates.

As for the photoelectric conversion part 10B, the Pt layer 11B is made of Pt and has a thickness of about 20 nm in the present embodiment. The Cr and Au layer 12B has a two-layer structure including a Cr layer and an Au layer having a thickness of about 20 nm and about 10 nm, respectively. The Cr2O3 layer 13B is a an oxide film layer interposed between the Pt layer 11B and the Cr and Au layer 12B. The Cr2O3 layer 13B is made of Cr2O3 and has a thickness of about 2 nm. There is a clearance C of about 500 to 1000 nm between the end of the Pt layer 11B and the cathode electrode 30B.

Considering the function of the photoelectric conversion part 10B, a Schottky junction between the Pt layer 11B and the Cr and Au layer 12B will suffice. Accrodingly, the material of the Pt layer 11B can be changed to Ag or Ni having a different work function from the Cr and Au layer 12B. The material of the Cr and Au layer 12B can be changed in a similar manner.

T anode electrode 20B in the present embodiment has a thickness of 100 nm and is made of Ag or Au. The cathode electrode 30B in the present embodiment has a thickness of 100 nm and is made of Ag or Au. These electrodes are joined respectively with the Pt layer 11B and the Cr and Au layer 12B such as to form ohmic junctions.

The electrode 20B is uniquely defined as an anode and the electrode 30B is uniquely defined as a cathode. This is because, unlike a conventional case, the cathode electrode 30B is out of electrical contact with the Pt layer 11B, making it possible to determine the moving direction of photocarriers (electrons/holes) generated near the Schottky interface S for each type of carriers. In the conventional case, each electrode can serve as an anode or a cathode due to contaminants mixed in a process of manufacturing a device or due to other disturbances, and this causes difficulty in increasing an open output voltage of a conventional element. However, the inventor newly tracked down the cause of this problem and has radically solved the problem with a very simple method of changing a relative positional relationship of the Pt layer 11B.

Reversing the Pt layer 11B and the Cr and Au layer 12B will reverse the anode-cathode relation of the electrodes. In addition, if an insulating member 111B of SiO2, SiN2, insulating organic substance, or other material is interposed in the clearance C as indicated by a broken line in FIG. 6, it is possible to finely adjust the open output voltage by selecting an appropriate material for the insulating member 111B.

The metal nanostructure 40B in the present embodiment is such that projections 41B are formed in a periodic or random manner at intervals d, etc. of an order of submicron (10-7 m) or nanometer (10-9 m) in a region between the anode electrode 20B and the cathode electrode 30B on the surface of the Pt layer 11B, so that light of all wavelength bands contained in incident light L is effectively absorbed by surface plasmon resonance. The metal nanostructure 40B will be described in detail below.

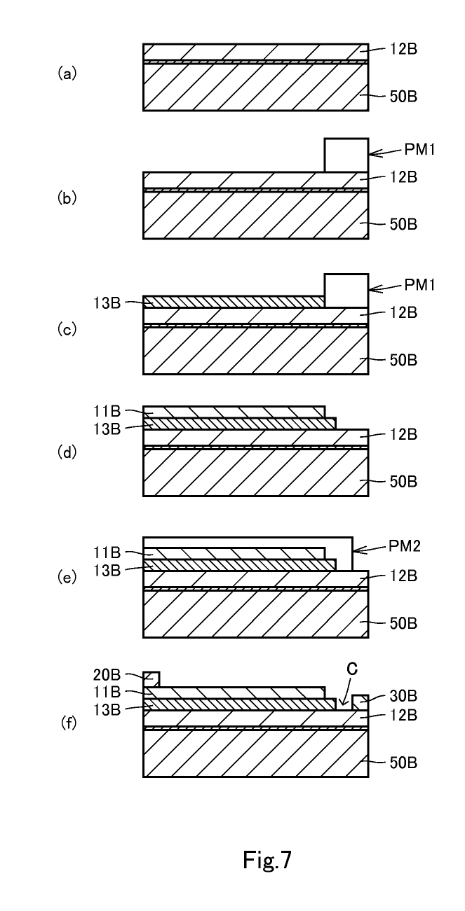

The following describes a method of manufacturing the photoelectric conversion device 100B configured as described above, with reference to FIG. 7.

Firstly, a base plate 50B already subjected to organic cleaning is prepared. An Au layer with a thickness of about 10 nm and a Cr layer with a thickness of about 20 nm are sequentially form on the surface of the base plate 50B by sputtering or other process and thereby form the Cr and Au layer 12B (see FIG. 7(a)). Then, patterning is conducted using a photomask PM1 by sputtering or other process to sequentially form the Cr2O3 layer 13B with a thickness of about 2 nm and the Pt layer 11B with a thickness of about 20 nm (see FIGS. 7(b), (c), (d), (e), and (f)). The clearance C is created in this process.

Then, patterning is conducted using a photomask PM2 by sputtering or other process to form the cathode electrode 30B of Ag or other material with a thickness of about 100 nm on the surface of the Cr and Au layer 12B. Similar patterning is conducted to form the anode electrode 20B of Ag or other material with a thickness of about 100 nm on the surface of the Pt layer 11B (see FIGS. 7(e) and (f)).

It should be noted that the projections 41B of the metal nanostructure 40B are formed concurrently with the formation of the anode electrode 20B on the surface of the Pt layer 11B. However, the projections 41B are not illustrated in FIG. 7, and the method of forming the projections 41B will be described later.

Through a series of the above processes the photoelectric conversion part 10B is fabricated. The photoelectric conversion part 10B is combined with the protection plate 60B along with internal wiring to fabricate the photoelectric conversion device 100B as illustrated on the left side in FIG. 9.

When the photoelectric conversion device is used as a tandem type, multiple photoelectric conversion devices 100B are stacked as shown on the right side in FIG. 9 and electrically connected to each other in parallel, in series, or in series parallel. The reference numerals 101B and 102B denote external output terminals.

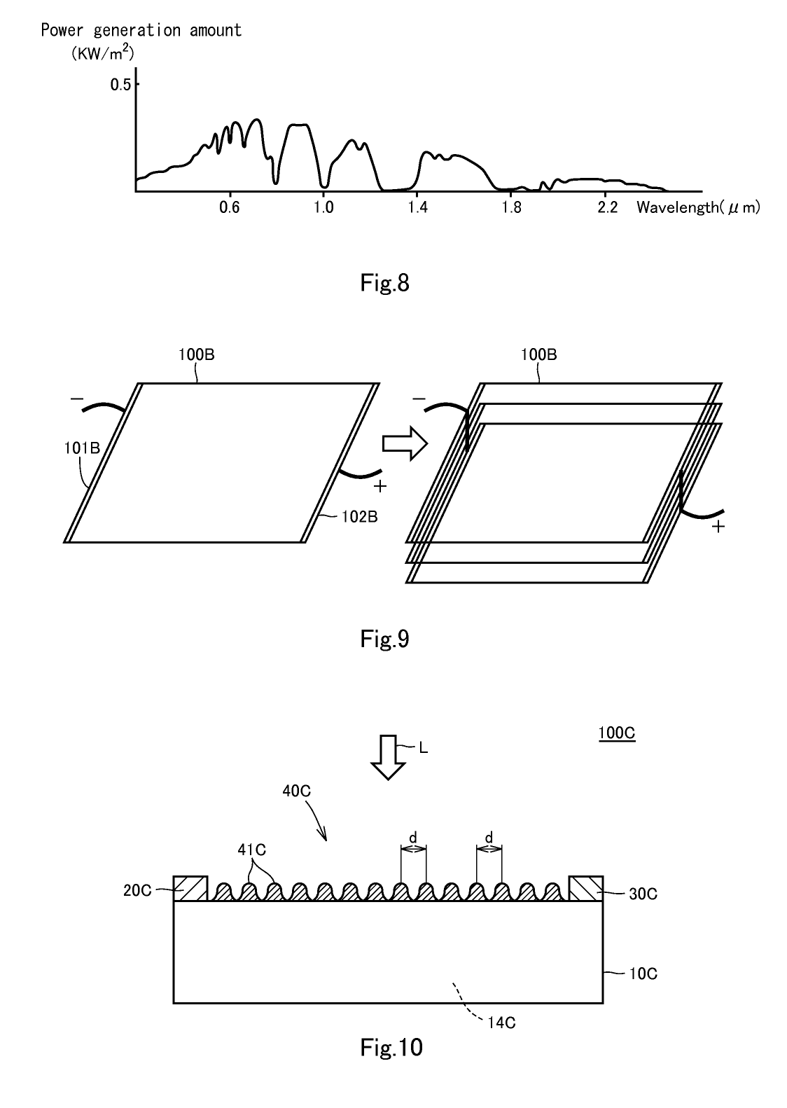

The photoelectric conversion device 100B thus fabricated provides a photoelectric conversion efficiency of about 10 to 12% and an open output voltage of about 0.8 to 1.2 V. The production cost is about one tenth of that of a conventional device at the same output level. The photoelectric conversion device 100A especially enables photoelectric conversion in a wide band from visible to infrared regions and exhibits optical characteristics as shown in FIG. 8.

### Third Embodiment

A photoelectric conversion device 100C illustrated in FIG. 10 includes a photoelectric conversion part 10C having a junction body 14C to absorb incident light L, and an anode electrode 20C and a cathode electrode 30C (corresponding to first and second electrodes) to extract photocarriers generated in the junction body 14C in accordance with the absorption of the incident light L. Of note, the photoelectric conversion part 10C has a metal nanostructure 40C in which projections 41C are formed in a periodic or random manner at intervals d, etc. of an order of submicron (10-7 m) or nanometer (10-9 m) on the surface of the layer of incidence of the junction body 14C, so that light of all wavelength bands contained in incident light L is effectively absorbed by surface plasmon resonance.

In the present embodiment, the junction body 14C of the photoelectric conversion part 10C is intended to be a Schottky-type photoelectric conversion part such as ones illustrated in FIG. 2, 6, or 13. However, the junction body 14C may also be a common photoelectric conversion part with a PIN structure in which photocarriers move in the thickness direction. The metal nanostructure 40C is formed on the layer of incidence (top layer) of the junction body 14C.

In the present embodiment, the anode electrode 20C and the cathode electrode 30C are formed on the surface of the top layer of the junction body 14C, at opposite sides of the metal nanostructure 40C.

The metal nanostructure 40C in the present embodiment is such that the projections 41C made of Ag or Au are formed in a periodic or random manner on the surface of the junction body 14C. The space d between the projections 41C (including the height, length, etc. of the projection 41C in some cases) is different in part, so that light of all wavelength bands contained in incident light L is effectively absorbed on the entire surface of the metal nanostructure 40C by surface plasmon resonance.

The space d etc. of the projections 41C is not constant throughout the entire surface of the junction body 14C, but changes periodically changed in some parts and randomly in other parts. With the metal nanostructure 40C having a large number of projections 41C as described above, light of all wavelength bands contained in the incident light L is effectively absorbed by surface plasmon resonance (see FIG. 12). For example, in the parts where the space d between the projections 41C is set to be up to about 100 nm, light of infrared to visible bands of not longer than about 1 μm is effectively absorbed, and in the parts where the space d between the projections 41C is set to be not up to about 150 nm, light of infrared bands of about 1 μm to 4 μm is effectively absorbed. The effective absorption of light with all wavelength bands contained in the incident light L in this way enables activation of photocarriers generated on the junction body 14C, enhancing the conversion efficiency of the photoelectric conversion.

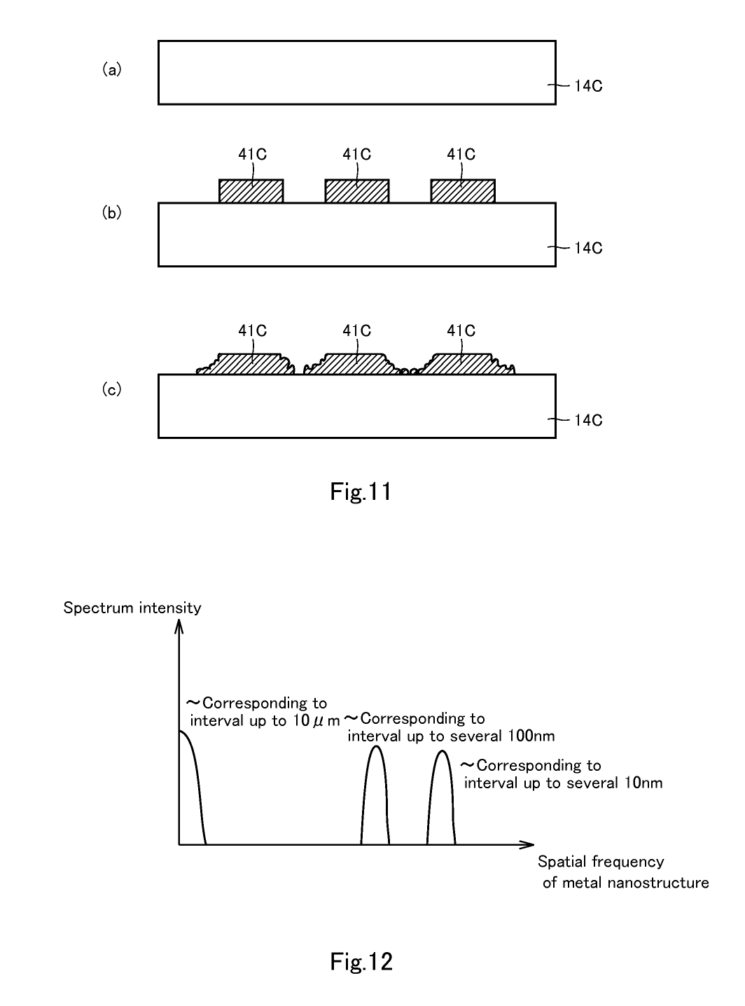

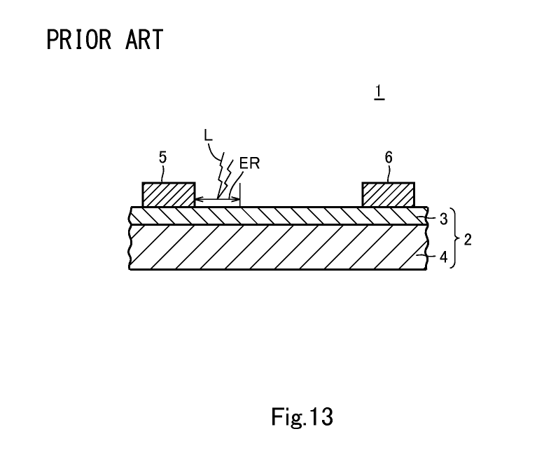

The following describes a method of manufacturing the photoelectric conversion device 100C configured as described above, with reference to FIG. 11.

In the present embodiment, the projections 41C of the metal nanostructure 40C are made of the same material as that of the anode electrode 20C and the cathode electrode 30C. Accordingly, the projections 41C of the metal nanostructure 40C are formed together with the anode electrode 20C and the cathode electrode 30C by a printing process (metal thin-film forming process such as screen printing or ink jet printing with ink or dispersion liquid paste of metal nanoparticles). It should be appeciated that the anode electrode 20C and the cathode electrode 30C are not illustrated in FIG. 11.

Specifically, in the formation of the metal nanostructure 40C on the photoelectric conversion part 10C, patterning is conducted by any of the above printing process to form the projections 41C on the surface of the junction body 12C of the photoelectric conversion part 10C, together with the anode electrode 20C and the cathode electrode 30C not illustrated (see FIGS. 11(a) and (b)). Then, annealing is performed at about 250 degrees to self-organize the projections 41C etc. (see FIG. 11(c)).

The photoelectric conversion part 10C having the metal nanostructure 40C is thus fabricated (the metal nanostructures 40A and 40B of the photoelectric conversion parts 10A and 10B described above are also formed in a similar manner). Then, the photoelectric conversion part 10C is combined with a base plate and a protection plate 60B along with internal wiring to fabricate the photoelectric conversion device 100C. It should be appreciated that the metal nanostructure 40C may not be formed during the electrode forming process as in the present embodiment, but the metal nanostructure 40C may be independently formed in a process different from the electrode forming process.

The photoelectric conversion device 100C thus fabricated provides a photoelectric conversion efficiency of about 30 to 40% at maximum. The production cost is about 20% of that of a conventional device at the same output level. The photoelectric conversion device 100C especially enables photoelectric conversion in a wide band from visible to infrared regions so as to actually provide a solar cell with high conversion efficiency and low cost.

### REFERENCE SIGNS LIST

100A Photoelectric conversion device
   10A Photoelectric conversion part
      11A CoSiₓ layer (first layer)
      12A Si layer (second layer)
      S Schottky interface
      20A Anode electrode (first electrode)
      30A Cathode electrode (second electrode)
      C Clearance
      (40A Metal nanostructure)
      (41A Projection)
100B Photoelectric conversion device
   10B Photoelectric conversion part
      11B Pt layer (first layer)
      12B Cr and Au layer (second layer)
      13B Cr₂O₃ layer (intermediate insulating layer)
      S Schottky interface
      20B Anode electrode (first electrode)
      30B Cathode electrode (second electrode)
      C Clearance
      40B Metal nanostructure
      41B Projection
100C Photoelectric conversion device
   10C Photoelectric conversion part
      14C Junction body
   20C Anode electrode (first electrode)
   30C Cathode electrode (second electrode)
   40C Metal nanostructure
   41C Projection

1. A photoelectric conversion device comprising:
a photoelectric conversion part including a first layer and a second layer, the first and second layers being joined to each other to form a Schottky junction;
a first electrode formed on the first layer; and
a second electrode formed on the second layer without electrical contact with the first layer in order to extract photocarriers, which move along an interface of the Schottky junction, in conjunction with the first electrode.

2. The photoelectric conversion device according to claim 1, further comprising
an insulating member interposed between an end of the first layer and the second electrode.

3. The photoelectric conversion device according to claim 1, wherein
the first layer is made of CoSiₓ, and the second layer is made of Si.

4. A manufacturing method of the photoelectric conversion device according to claim 3, comprising:
forming a pattern of the second electrode on a Si substrate corresponding to the second layer;
thereafter forming on the Si substrate a pattern of Co, which is a material of the first layer, and annealing the pattern to form the first layer on the Si substrate; and
thereafter forming a pattern of the first electrode on the first layer.

5. The photoelectric conversion device according to claim 1, wherein
the first layer is made of a metal or alloy and the second layer is made of another metal or alloy differing in work function from the metal or alloy of the first layer, and
the photoelectric conversion part further includes an intermediate insulating layer interposed between the first layer and the second layer.

6. A manufacturing method of the photoelectric conversion device according to claim 5, comprising:
forming the second layer on a surface of a base substrate;
thereafter sequentially forming a pattern of the intermediate insulating layer on the second layer and a pattern of the first layer on the intermediate insulating layer;
thereafter forming a pattern of the second electrode on the second layer; and
there before or thereafter forming a pattern of the first electrode on the first layer.

7. The photoelectric conversion device according to claim 1, wherein
the photoelectric conversion part has a metal nanostructure being such that projections of an order of submicron or nanometer are formed in a periodic or random manner on a surface of the first layer so that light of a predetermined wavelength band contained in incident light is effectively absorbed by surface plasmon resonance.

8. A manufacturing method of the photoelectric conversion device according to claim 7, comprising:
forming a pattern of the projections on the surface of the first layer of the photoelectric conversion part; and
thereafter annealing the pattern so as to form the metal nanostructure in the photoelectric conversion part.

9. A photoelectric conversion device comprising:
a photoelectric conversion part including a junction body; and
a first electrode and a second electrode in order to extract photocarriers generated on the junction body, wherein
the photoelectric conversion part has a metal nanostructure including projections of an order of submicron or nanometer formed in a periodic or random manner on a surface of a layer of incidence of the junction body so that light of a predetermined wavelength band contained in incident light is effectively absorbed by surface plasmon resonance.

10. A manufacturing method of the photoelectric conversion device according to claim 9, comprising:
forming a pattern of the projections on the surface of the layer of incidence the photoelectric conversion part; and
thereafter annealing the pattern so as to form the metal nanostructure on the photoelectric conversion part.

11. The photoelectric conversion device according to claim 2, wherein
the first layer is made of CoSiₓ, and the second layer is made of Si.

12. A manufacturing method of the photoelectric conversion device according to claim 11, comprising:
forming a pattern of the second electrode on a Si substrate corresponding to the second layer;
thereafter forming on the Si substrate a pattern of Co, which is a material of the first layer, and annealing the pattern to form the first layer on the Si substrate; and
thereafter forming a pattern of the first electrode on the first layer.

13. The photoelectric conversion device according to claim 2, wherein
the first layer is made of a metal or alloy and the second layer is made of another metal or alloy differing in work function from the metal or alloy of the first layer, and
the photoelectric conversion part further includes an intermediate insulating layer interposed between the first layer and the second layer.

14. A manufacturing method of the photoelectric conversion device according to claim 2, comprising:
forming the second layer on a surface of a base substrate;
thereafter sequentially forming a pattern of the intermediate insulating layer on the second layer and a pattern of the first layer on the intermediate insulating layer;
thereafter forming a pattern of the second electrode on the second layer; and
therebefore or thereafter forming a pattern of the first electrode on the first layer.

15. The photoelectric conversion device according to claim 2, wherein
the photoelectric conversion part has a metal nanostructure being such that projections of an order of submicron or nanometer are formed in a periodic or random manner on a surface of the first layer so that light of a predetermined wavelength band contained in incident light is effectively absorbed by surface plasmon resonance.

16. The photoelectric conversion device according to claim 3, wherein
the photoelectric conversion part has a metal nanostructure being such that projections of an order of submicron or nanometer are formed in a periodic or random manner on a surface of the first layer so that light of a predetermined wavelength band contained in incident light is effectively absorbed by surface plasmon resonance.

17. The photoelectric conversion device according to claim 5, wherein
the photoelectric conversion part has a metal nanostructure being such that projections of an order of submicron or nanometer are formed in a periodic or random manner on a surface of the first layer so that light of a predetermined wavelength band contained in incident light is effectively absorbed by surface plasmon resonance.

18. A manufacturing method of the photoelectric conversion device according to claim 15, comprising:
forming a pattern of the projections on the surface of the first layer of the photoelectric conversion part; and
thereafter annealing the pattern so as to form the metal nanostructure in the photoelectric conversion part.

19. A manufacturing method of the photoelectric conversion device according to claim 16, comprising:
forming a pattern of the projections on the surface of the first layer of the photoelectric conversion part; and
thereafter annealing the pattern so as to form the metal nanostructure in the photoelectric conversion part.

20. A manufacturing method of the photoelectric conversion device according to claim 17, comprising:
forming a pattern of the projections on the surface of the first layer of the photoelectric conversion part; and
thereafter annealing the pattern so as to form the metal nanostructure in the photoelectric conversion part.
